(19) United States
(12) Patent Application Publication
(10) Pub. No.: US 2024/0203835 A1
(43) Pub. Date: Jun. 20, 2024

(54) SEMICONDUCTOR DEVICE

(71) Applicant: ROHM CO., LTD., Kyoto (JP)

(72) Inventors: Masatsugu YUTANI, Kyoto (JP); Hajime KATAOKA, Kyoto (JP)

(73) Assignee: ROHM CO., LTD., Kyoto (JP)

(21) Appl. No.: 18/537,850

(22) Filed: Dec. 13, 2023

(30) Foreign Application Priority Data
Dec. 15, 2022 (JP) 2022-200307

(51) Int. Cl. H01L 23/495; H01L 21/66; H01L 23/00; H01L 25/065

(52) U.S. Cl. CPC H01L 23/4951; H01L 22/32; H01L 23/4952; H01L 23/49575; H01L 24/08; H01L 24/48; H01L 25/0652; H01L 2224/08137; H01L 2224/08225; H01L 2224/48227; H01L 2224/48247; H01L 2924/01013; H01L 2924/01029; H01L 2924/13055; H01L 2924/1306

(57) ABSTRACT

There is provided a semiconductor device including a semiconductor chip including a first main surface and a second main surface opposite to the first main surface, an element region formed on the first main surface and including an element part, and a non-element region outside the element region, an insulating layer covering the element region and the non-element region, a first pad formed on the insulating layer and electrically connected to the element part, a second pad formed on the insulating layer and electrically connected to the element part via a path electrically separated from the first pad, a first uneven structure formed by a buried body, which has conductivity and is buried in the insulating layer, below the first pad of the insulating layer, and a second uneven structure formed by deposits deposited on a surface of the insulating layer, below the second pad of the insulating layer.

### CROSS-REFERENCE TO RELATED APPLICATION

This application is based upon and claims the benefit of priority from Japanese Patent Application No. 2022-200307, filed on Dec. 15, 2022, the entire contents of which are incorporated herein by reference.

### TECHNICAL FIELD

The present disclosure relates to a semiconductor device.

### BACKGROUND

The related art discloses a semiconductor device that includes an Al pad electrode on which unevenness is formed and an Au wire bonded to the Al pad electrode. The Al pad electrode has an uneven shape. The Au wire is connected to the Al pad electrode by thermo-compressing a ball portion of the Au wire to the Al pad electrode.

Further, the related art discloses a semiconductor device that includes an insulating layer formed on an upper surface of a semiconductor element, a bonding pad formed on the insulating layer, and a gold wire having a ball portion connected to the bonding pad. A plurality of recesses are formed in the bonding pad.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is a view showing a planar structure of an element region in FIG. 1.

FIG. 3 is a view showing a cross-section taken along line III-III in FIG. 2.

FIG. 4 is an enlarged view of a portion surrounded by two-dot chain line IV in FIG. 1.

FIG. 5 is a view showing a cross-section taken along line V-V in FIG. 4.

FIG. 6 is a view showing a planar structure of a non-element region.

FIG. 7 is an enlarged view showing a planar structure of a portion surrounded by two-dot chain line VII in FIG. 1.

FIGS. 8A and 8B are views showing a part of a manufacturing process of the semiconductor device according to the first embodiment of the present disclosure.

FIGS. 9A and 9B are views showing next steps of FIGS. 8A and 8B, respectively.

FIGS. 10A and 10B are views showing next steps of FIGS. 9A and 9B, respectively.

FIGS. 11A and 11B are views showing next steps of FIGS. 10A and 10B, respectively.

FIGS. 12A and 12B are views showing next steps of FIGS. 11A and 11B, respectively.

FIGS. 13A and 13B are views showing next steps of FIGS. 12A and 12B, respectively.

FIGS. 14A and 14B are views showing next steps of FIGS. 13A and 13B, respectively.

FIGS. 15A and 15B are views showing next steps of FIGS. 14A and 14B, respectively.

FIGS. 16A and 16B are views showing next steps of FIGS. 15A and 15B, respectively.

FIGS. 17A and 17B are views showing next steps of FIGS. 16A and 16B, respectively.

FIG. 18 is a view corresponding to FIG. 6, showing a layout of a second uneven structure of a first modification of the present disclosure.

FIG. 19 is a view corresponding to FIG. 6, showing a layout of a second uneven structure of a second modification of the present disclosure.

FIG. 20 is a view corresponding to FIG. 6, showing a layout of a second uneven structure of a third modification of the present disclosure.

FIG. 21 is a view corresponding to FIG. 6, showing a layout of a second uneven structure of a fourth modification of the present disclosure.

FIG. 22 is a view corresponding to FIG. 6, showing a layout of a second uneven structure of a fifth modification of the present disclosure.

FIG. 23 is a view corresponding to FIG. 6, showing a layout of a second uneven structure of a sixth modification of the present disclosure.

FIG. 24 is a diagram corresponding to FIG. 6, showing a layout of a second uneven structure of a seventh modification of the present disclosure.

FIG. 25 is a view corresponding to FIG. 5, showing a cross-section of a semiconductor device according to a second embodiment of the present disclosure.

FIG. 26 is a view corresponding to FIG. 5, showing a cross-section of a semiconductor device according to a third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

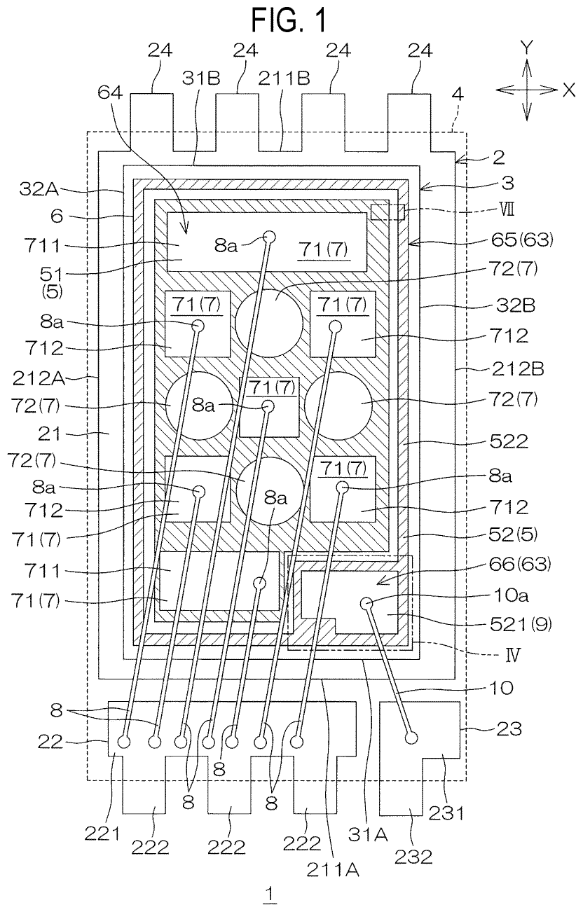

FIG. 1 is a schematic plan view of a semiconductor device 1 according to a first embodiment of the present disclosure. For the sake of clarity, in FIG. 1, a package 4 is shown with an imaginary line (broken line), and other components are shown with solid lines.

The semiconductor device 1 includes a lead frame 2, a semiconductor element 3, and the package 4.

The lead frame 2 is formed in a metal plate shape. The lead frame 2 is formed from a thin metal plate such as Cu that has a rectangular shape in a plan view by punching, cutting, bending, or the like. Therefore, a main component of a material of the lead frame 2 is Cu. Further, the material of the lead frame 2 is not limited thereto.

The lead frame 2 may include a die pad part 21, a first lead part 22, a second lead part 23, and a third lead part 24. In this embodiment, the first lead part 22, the second lead part 23, and the third lead part 24 may be referred to as a source lead part, a gate lead part, and a drain lead part, respectively. Further, since the first lead part 22, the second lead part 23, and the third lead part 24 include a portion exposed from the package 4 and connected to an external circuit of the semiconductor device 1, the first lead part 22, the second lead part 23, and the third lead part 24 may also be referred to as a first terminal (source terminal), a second terminal (gate terminal), and a third terminal (drain terminal), respectively.

In a plan view, the die pad part 21 has a quadrangular shape including a pair of first sides 211A and 211B extending in a first direction X and a pair of second sides 212A and 212B extending in a second direction Y that intersects (in this embodiment, is orthogonal to) the first direction X.

The first lead part 22, the second lead part 23, and the third lead part 24 are arranged around the die pad part 21. In this embodiment, the first lead part 22, the second lead part 23, and the third lead part 24 are arranged adjacent to the first sides 211A and 211B of the die pad part 21. More specifically, the first lead part 22 and the second lead part 23 are arranged adjacent to one first side 211A of the die pad part 21, and the third lead part 24 is arranged adjacent to the other first side 211B of the die pad part 21. That is, the first lead part 22 and the second lead part 23 are arranged on opposite sides of the third lead part 24 with the die pad part 21 interposed between.

The first lead part 22 is formed apart from the die pad part 21. The first lead part 22 may include a first pad part 221 and a first lead 222. The first pad part 221 is formed in a substantially rectangular shape that is elongated along the first side 211A of the die pad part 21 in a plan view. The first lead 222 is integrally formed with the first pad part 221 and extends from the first pad part 221 in a direction intersecting a longitudinal direction of the first pad part 221. A plurality of first leads 222 (three first leads 222 in this embodiment) are formed. The plurality of first leads 222 are arranged at intervals along the longitudinal direction of the common first pad part 221 and are connected to the common first pad part 221.

The second lead part 23 is formed apart from the die pad part 21 and the first lead part 22. The second lead part 23 may include a second pad part 231 and a second lead 232. The second pad part 231 is formed in a substantially rectangular shape that is elongated along the first side 211A of the die pad part 21. The second lead 232 is integrally formed with the second pad part 231 and extends from the second pad part 231 in a direction intersecting a longitudinal direction of the second pad part 231. The second lead 232 is connected to the second pad part 231 on a one-to-one basis. In this embodiment, the second lead part 23 is arranged near one end (one corner of the die pad part 21) of one first side 211A of the die pad part 21, and the first lead part 22 extends along the first side 211A of the die pad part 21 from the one end toward the other end.

The third lead part 24 is integrally formed with the die pad part 21, unlike the first lead part 22 and the second lead part 23. The third lead part 24 extends from the other first side 211B of the die pad part 21 in a direction intersecting the first side 211B. A plurality of third lead parts 24 (four third lead parts 24 in this embodiment) are formed. The plurality of third lead parts 24 are arranged at intervals along the first side 211B of the die pad part 21.

The semiconductor element 3 is placed on the die pad part 21 of the lead frame 2 and is supported by the die pad part 21. The semiconductor element 3 includes a pair of first sides 31A and 31B and a pair of second sides 32A and 32B and has a quadrangular shape smaller than the die pad part 21 in a plan view. In this embodiment, the semiconductor element 3 is placed on the die pad part 21 so that the first sides 31A and 31B become parallel to the first sides 211A and 211B of the die pad part 21 and the second sides 32A and 32B become parallel to the second sides 212A and 212B of the die pad part 21.

A conductive film 5 and a protective film 6 are formed on one surface (in this embodiment, an upper surface) of the semiconductor element 3. The conductive film 5 is formed over almost the entire upper surface of the semiconductor element 3. The protective film 6 is, for example, an insulating film such as SiN. The conductive film 5 is partially covered with the protective film 6. In FIG. 1, a portion of the conductive film 5 covered with the protective film 6 is shown as a hatched region, and a portion of the conductive film 5 exposed from the protective film 6 is shown as a white region. The conductive film 5 is a portion to which a first wire 8 and a second wire 10, which will be described later, are connected, and may be referred to as an electrode film or a surface electrode film.

The conductive film 5 may include a first conductive film 51 and a second conductive film 52. The first conductive film 51 and the second conductive film 52 are formed separated from each other. A region around the first conductive film 51 may be an outer region 63. In other words, when a region where the first conductive film 51 is formed (a region covered with the first conductive film 51) is referred to as an element region 64, the outer region 63 is a region outside the element region 64 and a region surrounding the element region 64. The outer region 63 includes an annular outer peripheral region 65 formed along an outer periphery of the semiconductor element 3 and a non-element region 66 arranged at one corner of the upper surface of the semiconductor element 3. The non-element region 66 may also be referred to as a corner region.

A portion of the first conductive film 51 is exposed from the protective film 6, as a plurality of first pads 7 (eleven first pads 7 in the example of FIG. 1). The plurality of first pads 7 include a plurality of wire connection pads 71 (seven wire connection pads 71 in the example of FIG. 1) and a plurality of test pads 72 (four test pads 72 in the example of FIG. 1). The wire connection pad 71 is a pad for connecting the first wire 8. In the example of FIG. 1, the seven wire connection pads 71 include two first connection pads 711 arranged at both ends of the first conductive film 51 in the second direction Y and five second connection pads 712 sandwiched between the two first connection pads 711 in the second direction Y. The two first connection pads 711 are elongated in the first direction X and have a rectangular shape in a plan view. The five second connection pads 712 have a square shape in a plan view. Among the five second connection pads 712, one second connection pad 712 is surrounded by the other four second connection pads 712.

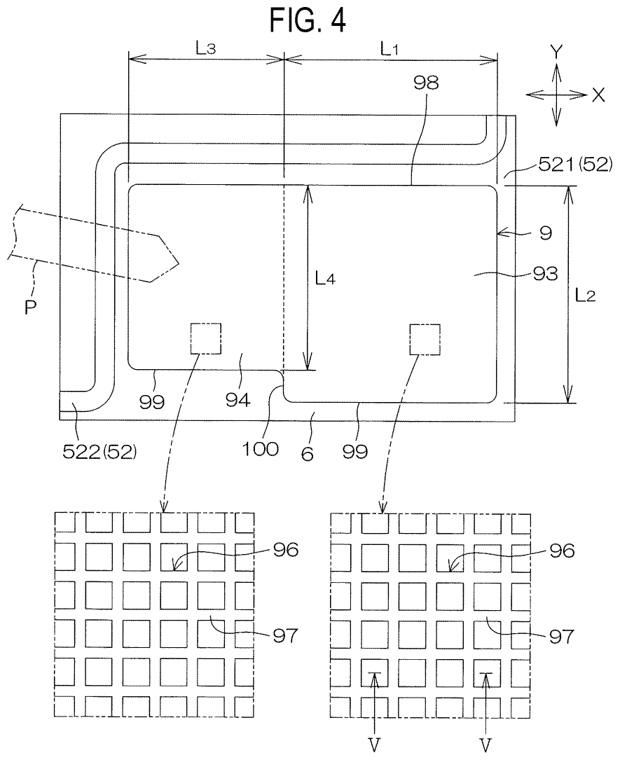

A test pad 72 is a pad for contacting a test member P for testing (for example, a probe, see FIG. 4). In the example of FIG. 1, the test pad 72 has a circular shape in a plan view. The four test pads 72 are arranged to be sandwiched between the two first connection pads 711 in the second direction Y. The four test pads 72 are arranged to surround a second connection pad 712 located at a center of the five second connection pads 712. In this embodiment, the plurality of first pads 7 are divided into wire connection pads 71 and test pads 72. During the test, when the test member P comes into contact with a pad (the first pad 7), there is a possibility that an impression may be formed on the pad. If a wire (the first wire 8) is connected to a position where this impression is formed, there is a possibility that a bonding strength of the wire will be reduced. In this embodiment, since the test pad 72 is a pad different from the wire connection pad 71, it is possible to avoid a reduction in the bonding strength of the wire (the first wire 8) due to the above-mentioned impression.

The first wire 8 is connected to the wire connection pad 71. The first wire 8 includes a bump-shaped tip 8a. By bonding the tip 8a to the wire connection pad 71 (the first pad 7), the tip 8a is connected to the wire connection pad 71.

In this embodiment, the first wire 8 may be a so-called Cu wire containing Cu as a main component. As a modification, the first wire 8 may be an Au wire or an Al wire. A diameter of the first wire 8 may have, for example, in the case of a Cu wire, a diameter of 30 μm or more and 70 μm or less.

The second conductive film 52 may integrally include a pad electrode part 521 and a finger electrode part 522. The pad electrode part 521 is formed in the outer region 63 and, in this embodiment, is arranged in the non-element region 66. The finger electrode part 522 is formed in the outer region 63 and is formed in the outer peripheral region 65 along a peripheral edge portion of the semiconductor element 3 from the pad electrode part 521. In this embodiment, the finger electrode part 522 is formed along the first sides 31A and 31B and the second sides 32A and 32B of the semiconductor element 3 to surround the first conductive film 51. The finger electrode part 522 is covered with the protective film 6, while a portion of the pad electrode part 521 is exposed from the protective film 6, as a second pad 9.

The second wire (bonding wire) 10 is connected to the second pad 9. The second wire 10 connects the second pad 9 and the second pad part 231 of the second lead part 23. The second wire 10 has a bump-shaped tip 10a. The tip 10a is connected to the second pad 9 by being bonded the tip 10a to the second pad 9 (more specifically, a wire connection region 93 to be described later).

In this embodiment, the second wire 10 may be a so-called Cu wire containing Cu as a main component. Moreover, since a current flowing through a gate is relatively small, an Au wire having a lower electric conductivity than the Cu wire may be used as the second wire 10. During wire bonding, a plurality of deposits 92 (which will be described later) forming a second uneven structure 91 (which will be described later) functions as a shock absorbing material. Regardless of whether the Cu wire or the Au wire is used as the second wire 10, the time required for ultrasonic bonding is short, thereby suppressing or preventing the occurrence of cracks at the tip 10a. In particular, when the Cu wire with high hardness is used as the second wire 10, the advantage of the shock absorbing effect is large. For example, in the case of the Cu wire, the second wire 10 may have a diameter of 30 μm or more and 70 μm or less.

The package 4 covers the semiconductor element 3, the first wire 8, the second wire 10, and a portion of the lead frame 2, and may be called a sealing resin. The package 4 is made of an insulating material. In this embodiment, the package 4 is made of, for example, epoxy resin.

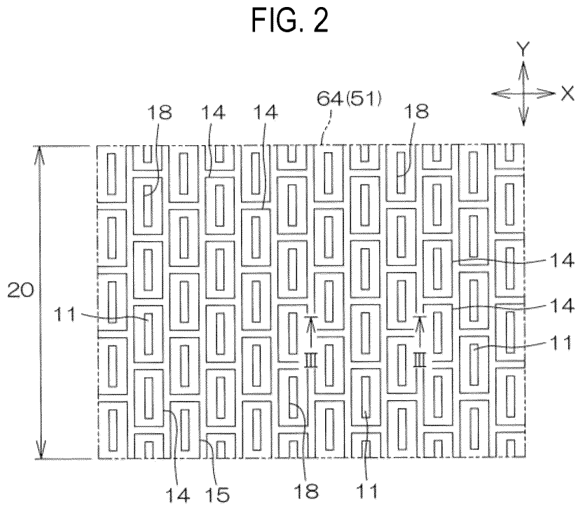

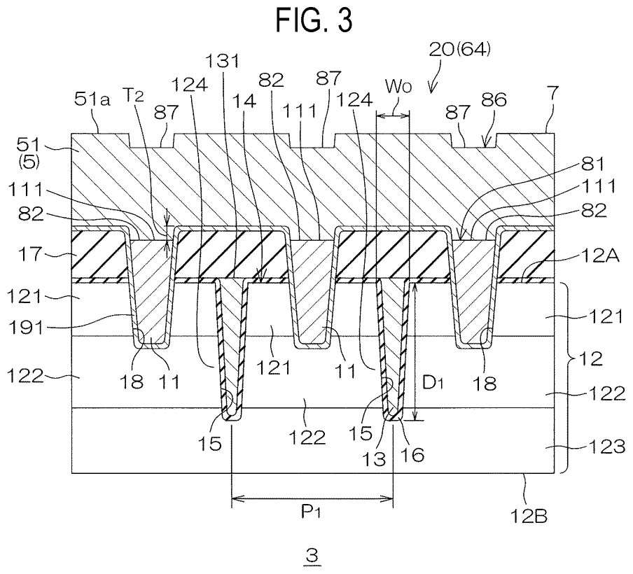

FIG. 2 is a partially enlarged view showing a planar structure of the element region 64 in FIG. 1. FIG. 3 is a view showing a cross-section taken along line III-III in FIG. 2.

The semiconductor device 1 includes a semiconductor chip 12.

The semiconductor chip 12 forms an outer shape of the semiconductor element 3 and is, for example, a structure in which a single crystal semiconductor material is formed in a chip shape (rectangular parallelepiped shape). The semiconductor chip 12 is made of a semiconductor material such as Si or SiC. The semiconductor chip 12 includes a first main surface 12A and a second main surface 12B opposite to the first main surface 12A. The first main surface 12A is a device surface on which a functional device is formed. The second main surface 12B is a non-device surface on which no functional device is formed. In this embodiment, the semiconductor chip 12 may include at least one selected from the group of a semiconductor substrate and an epitaxial layer.

An element part 20 as an example of the functional device is formed in the element region 64 of the first main surface 12A of the semiconductor chip 12. The element part 20 is selectively arranged in a region below the first conductive film 51, as shown in FIG. 2. The element part 20 is not arranged in a region below the second conductive film 52. The element part 20 is a portion through which a current flows in a thickness direction of the semiconductor chip 12, when a source and a drain of the semiconductor device 1 are in a conductive state (on state).

Referring to FIG. 3, the element part 20 includes a first impurity region 121 (the source), a second impurity region 122 (a body), a third impurity region 123 (the drain), a gate trench 15, a gate insulating film 16, and a gate electrode 13.

The first impurity region 121 is a p-type impurity region that is selectively formed in a surface layer portion of the first main surface 12A of the semiconductor chip 12, below the first conductive film 51, as shown in FIG. 3. A p-type impurity concentration of the first impurity region 121 may be 1×10¹⁸ cm⁻³ or more and 1×10²⁰ cm⁻³ less.

The second impurity region 122 is an n-type impurity region that is formed in the surface layer portion of the first main surface 12A of the semiconductor chip 12. The second impurity region 122 is formed to be in contact with the first impurity region 121 at an interval from the first main surface 12A to the second main surface 12B side. That is, the second impurity region 122 faces the first main surface 12A with the first impurity region 121 interposed therebetween.

An n-type impurity concentration of the second impurity region 122 may be 1×10¹⁵ cm⁻³ or more and 1×10¹⁹ cm⁻³ or less.

The third impurity region 123 is a p-type impurity region that is formed in a surface layer portion of the second main surface 12B of the semiconductor chip 12. The third impurity region 123 is formed in contact with the second impurity region 122 and over the entire surface layer portion of the second main surface 12B, and is exposed from the second main surface 12B. A p-type impurity concentration of the third impurity region 123 is lower than the p-type impurity concentration of the first impurity region 121 and may be, for example, 1×10¹⁸ cm⁻³ or more and 1×10²¹ cm⁻³ or less. A thickness of the third impurity region 123 may be 1 μm or more and 500 μm or less.

The gate trench 15 is a recess that penetrates the first impurity region 121 and the second impurity region 122, and reaches the third impurity region 123. As shown in FIG. 2, the gate trench 15 surrounds the first impurity region 121, the second impurity region 122, and the third impurity region 123, thereby partitioning transistor cells 14 including these regions 121, 122, and 123.

In FIG. 2, an arrangement pattern of the transistor cells 14 is staggered. Although not shown, the arrangement pattern of the transistor cells 14 may be a matrix or a stripe. Each transistor cell 14 is formed in a quadrangular shape in a plan view as shown in FIG. 2, and in this embodiment, it is formed in a rectangular shape.

The gate trench 15 is formed between a plurality of transistor cells 14 arranged as described above. The gate trench 15 is formed in a tapered shape with an opening width W₀ gradually narrowing toward a depth direction of the gate trench 15. The width W₀ of the gate trench 15 may be, for example, 0.17 μm or more and 0.22 μm or less at an open end of the gate trench 15. Further, as shown in FIG. 3, a pitch P₁ between adjacent gate trenches 15 is, for example, 0.8 μm or more and 1.2 μm or less. As shown in FIG. 2, when the gate trenches 15 are continuous to surround the plurality of transistor cells 14, the pitch P₁ of the gate trenches 15 is, for example, a distance between gate trenches 15 facing each other with one transistor cell 14 interposed therebetween. Further, a depth D₁ of the gate trench 15 may be, for example, 0.8 μm or more and 1.2 μm or less.

The gate insulating film 16 covers an inner surface of the gate trench 15, as shown in FIG. 3. Further, the gate insulating film 16 covers the first main surface 12A of the semiconductor chip 12. The gate insulating film 16 is made of an insulating material containing, for example, SiO₂, SiN, or the like.

The gate electrode 13 faces the second impurity region 122 with the gate insulating film 16 interposed therebetween. In the second impurity region 122, a side surface portion of the gate trench 15 facing the gate electrode 13 is a channel region 124. By applying a voltage to the gate electrode 13, carriers (electrons in this embodiment) are induced in the channel region 124, and conduction occurs between the first impurity region 121 and the third impurity region 123.

As shown in FIG. 3, the gate electrode 13 may include an upper surface 131 that is flush with the first main surface 12A of the semiconductor chip 12 or recessed toward the second main surface 12B.

An insulating layer 17 is formed on the first main surface 12A of the semiconductor chip 12. The insulating layer 17 covers the element region 64 including the transistor cell 14 and the gate electrode 13. The insulating layer 17 is an interlayer insulating film that insulates the gate electrode 13 and the first conductive film 51. The insulating layer 17 is made of an insulating material containing SiO₂, SiN, or the like.

As shown in FIGS. 2 and 3, a source trench 18 is formed to correspond to each transistor cell 14. In this embodiment, one source trench 18 is formed to correspond to each transistor cell 14, but a plurality of source trenches 18 may be formed to correspond to each transistor cell 14. The source trench 18 is formed in an elongated rectangular shape in a plan view along a longitudinal direction of the transistor cell 14 which has a rectangular shape in a plan view.

As shown in FIG. 3, the source trench 18 is a recess that penetrates the insulating layer 17, the gate insulating film 16, and the first impurity region 121, and reaches the second impurity region 122. The source trench 18 is formed in a tapered shape with an opening width gradually narrowing toward a depth direction of the source trench 18. Further, a pitch between adjacent source trenches 18 is the same as the pitch P₁ of gate trenches 15 and is, for example, 1 μm or less (for example, 0.95 μm).

A contact plug 11 (a conductive buried body) is buried in the source trench 18. The contact plug 11 is buried in the source trench 18 with a first barrier film 191 interposed therebetween. With such a configuration, it is possible to alleviate the electric field concentration at a bottom of the gate trench 15 and provide the semiconductor device 1 with improved reliability.

The first barrier film 191 suppresses a material forming the contact plug 11 from diffusing into the insulating layer 17. In this embodiment, the material of the contact plug 11 is W (tungsten). The first barrier film 191 may include a material containing Ti (for example, a single layer structure of Ti or a stacked structure of Ti and TiN). A thickness of the first barrier film 191 is, for example, 500 Å or more and 700 Å or less.

The first barrier film 191 includes one surface and the other surface formed to follow an inner surface of the source trench 18 and an upper surface of the insulating layer 17, and has direct conduction with the first impurity region 121 and the second impurity region 122. Further, the first barrier film 191 is continuous across an upper region of the gate trench 15, which is a boundary between adjacent transistor cells 14.

The contact plug 11 is electrically connected to the first impurity region 121 and the second impurity region 122 via the first barrier film 191. As a result, the contact plug 11 is electrically connected to the element part 20.

An upper surface 111 of the contact plug 11 is recessed toward the first main surface 12A of the semiconductor chip 12 with respect to the upper surface of the insulating layer 17. In other words, a recess (an unevenness) 82 is defined by the upper surface of the insulating layer 17 and the upper surface 111 of the contact plug 11. In this embodiment, the recess 82 is formed to correspond to each of the plurality of transistor cells 14 arranged in a staggered manner. As a result, a plurality of recesses 82 are formed on the insulating layer 17 above the element region 64 in a staggered manner, in a plan view. A first uneven structure 81 is formed by the plurality of recesses 82 on the insulating layer 17 above the element region 64.

In other words, the plurality of recesses 82 form unevenness with the upper surface of the insulating layer 17. In the first uneven structure 81, a height difference T₁ of the unevenness formed by the plurality of recesses 82 is 100 nm or more and 200 nm or less.

The first conductive film 51 is formed on the insulating layer 17 above the element region 64. The first conductive film 51 is electrically connected to the first impurity region 121 and the second impurity region 122 via the contact plug 11 and the first barrier film 191. That is, the first conductive film 51 is electrically connected to the transistor cell 14. The first conductive film 51 is made of a material containing, for example, Al, and, in this embodiment, is made of AlCu.

A surface uneven structure 86 including a plurality of recesses 87 is formed on a surface 51a of the first conductive film 51. The surface uneven structure 86 takes after a shape of the first uneven structure 81. Specifically, the recesses 87 are formed on the surface 51a of the first conductive film 51 at a position facing the upper surface 111 in a stacking direction of the first conductive film 51. The surface uneven structure 86 is formed over the entire surface 51a of the first conductive film 51.

A portion of the first conductive film 51 is the first pad 7. In other words, the first pad 7 is an output pad of the element part 20. The first pad 7 may be referred to as a source pad based on its electrical connection target. A plurality of first uneven structures 81 are formed in a region below the first pad 7, and the surface uneven structure 86 is formed on the first pad 7. The surface uneven structure 86 is formed on the wire connection pad 71 (see FIG. 1) and the test pad 72 (see FIG. 1). A height difference of the unevenness in the surface uneven structure 86 is the same as the height difference T₁ of the unevenness in the first uneven structure 81.

Although not shown, a drain electrode layer connected to the third impurity region 123 is formed on the second main surface 12B of the semiconductor chip 12.

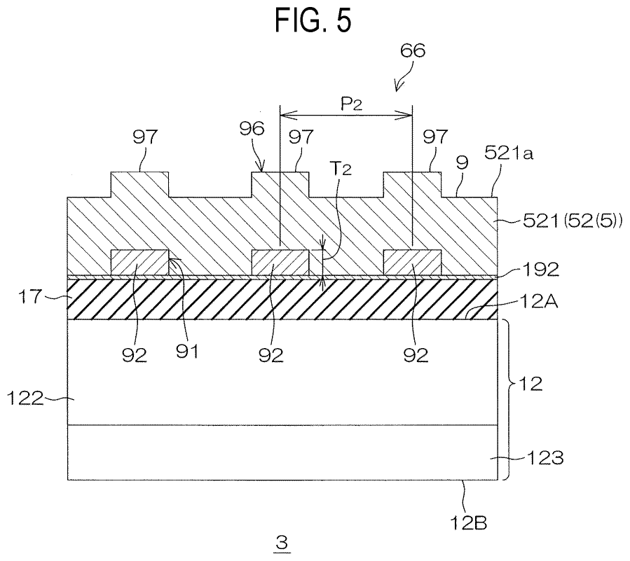

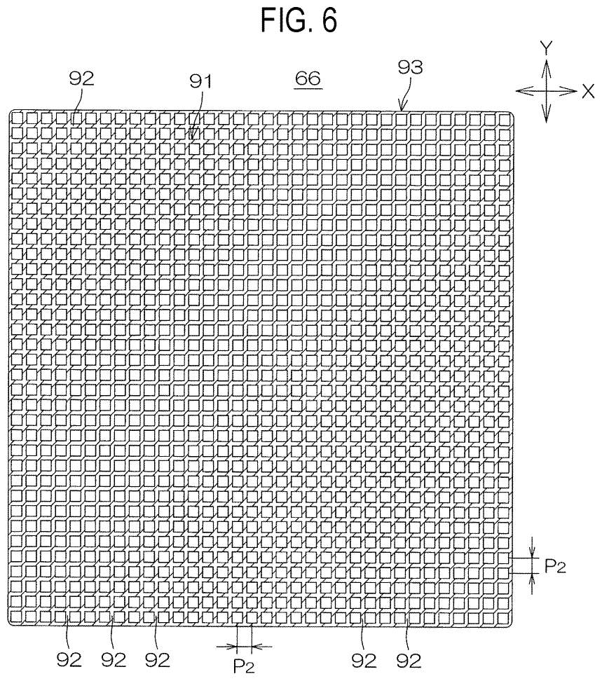

FIG. 4 is an enlarged view of a portion surrounded by two-dot chain line IV in FIG. 1. FIG. 5 is a view showing a cross-section taken along line V-V in FIG. 4. FIG. 6 is a view showing a planar structure of the non-element region 66. In FIG. 6, the non-element region 66 below the wire connection region 93 of the second pad 9 is shown, and the deposits 92 are indicated by a hatched region.

As shown in FIG. 4, a portion of the pad electrode part 521 is exposed from the protective film 6, as the second pad 9. A portion of the pad electrode part 521 of the second conductive film 52 is the second pad 9. In other words, the second pad 9 is a control pad that controls a current of the element part 20. The second pad 9 may be referred to as a gate pad based on its electrical connection target.

The second pad 9 includes the wire connection region 93 and a test region 94. The wire connection region 93 is a region for connecting the second wire 10. The wire connection region 93 has a quadrangular shape in a plan view, and more specifically, a square shape in a plan view. The length L₁ in the first direction X and the length L₂ in the second direction Y of the wire connection region 93 are each 150 μm or more and 200 μm or less.

The test region 94 is a region for contacting the test member P for testing. The test region 94 is drawn out from the wire connection region 93 along the first direction X and is formed integrally with the wire connection region 93. The length L₃ in the first direction X and the length L₄ in the second direction Y of the test region 94 are smaller than the length L₁ and the length L₂, respectively. An integrated region of the wire connection region 93 and the test region 94, each of which has a quadrangular shape in a plan view, includes a pair of first side 98 and second side 99 facing each other. The first side 98 is a straight line spanning the wire connection region 93 and the test region 94, and the second side 99 is a straight line separated by a step 100 at a boundary between the wire connection region 93 and the test region 94.

The reason that the second pad 9 is divided into the wire connection region 93 and the test region 94 is to avoid a reduction in a bonding strength of a wire (the second wire 10) due to the wire (the second wire 10) being connected to a position where the above-mentioned impression (the impression caused by contact with the test member P) is formed.

As shown in FIG. 5, the semiconductor device 1 includes the aforementioned second impurity region 122 and third impurity region 123 as impurity regions in the non-element region 66. The second impurity region 122 is exposed from the first main surface 12A of the semiconductor chip 12. An element part (corresponding to the element part 20) is not formed in the non-element region 66.

As shown in FIG. 5, in the non-element region 66, the semiconductor device 1 includes a plurality of protruding deposits (an unevenness) 92. Here, “the plurality of deposits 92” means that they are separated into a plurality of parts in a cross-sectional view, but may be integrated in a plan view. The plurality of deposits 92 are arranged on an upper surface of the insulating layer 17 on the non-element region 66. Adjacent deposits 92 are spaced apart from each other. The second uneven structure 91 is formed on the upper surface of the insulating layer 17 by the plurality of deposits 92 and the upper surface of the insulating layer 17. The plurality of deposits 92 form the unevenness with the upper surface of the insulating layer 17. The deposit 92 has a quadrangular cross-sectional shape orthogonal to a direction in which the deposit 92 extends. No other deposits exist between a plurality of adjacent deposits 92. The deposit 92 may be electrically conductive. In this embodiment, the deposit 92 is made of the same material as the contact plug 11, and is W (tungsten).

As shown in FIG. 6, the plurality of deposits 92 of the second uneven structure 91 are connected to each other and arranged in a lattice shape, in a plan view. Although FIG. 6 shows the non-element region 66 covered by the wire connection region 93, the second uneven structure 91 is also formed in the non-element region 66 covered by the test region 94. In the second uneven structure 91, the deposits 92 are adjacent to each other at a constant pitch P₂ in the first direction X and the second direction Y (see also FIG. 5). In this embodiment, the pitch P₂ is 5 μm in both directions. Since the pitch P₂ is relatively large at 5 μm, it is easy to arrange the deposits 92 in a desired pattern, and therefore the second uneven structure 91 can be easily formed.

In the second uneven structure 91, a height difference T₂ of the unevenness formed by the plurality of deposits 92 is 250 nm or more and 350 nm or less. In other words, the unevenness of the second uneven structure 91 is larger than the unevenness of the first uneven structure 81.

As shown in FIG. 5, the pad electrode part 521 included in the second conductive film 52 is formed on the insulating layer 17 on the non-element region 66 with a second barrier film 192 interposed therebetween. A surface uneven structure 96 consisting of a plurality of convex portions 97 is formed on the surface 521a of the pad electrode part 521 (see also FIG. 4). The surface uneven structure 96 takes after the shape of the second uneven structure 91. That is, the surface uneven structure 96 has a lattice shape in a plan view. The convex portions 97 are formed on the surface 521a of the pad electrode part 521 at positions facing the deposits 92 in a stacking direction of the pad electrode part 521. A height difference of the unevenness in the surface uneven structure 96 is the same as the height difference T₂ of the unevenness in the second uneven structure 91.

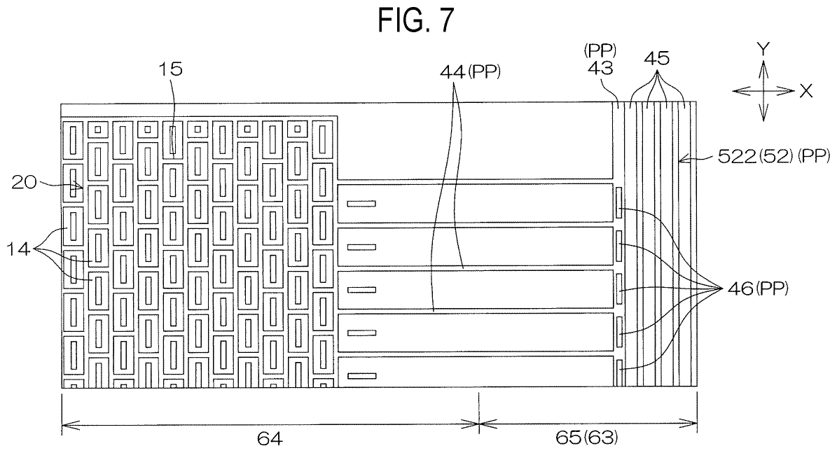

FIG. 7 is an enlarged view showing a planar structure of a portion surrounded by two-dot chain line VII in FIG. 1. As impurity regions in the outer peripheral region 65, the semiconductor device 1 includes the aforementioned second impurity region 122 and third impurity region 123. The second impurity region 122 is exposed from the first main surface 12A of the semiconductor chip 12. An element part (corresponding to the element part 20) is not formed in the outer peripheral region 65.

The semiconductor device 1 includes a first outer peripheral electrode 43, a connection electrode 44, a plurality of second outer peripheral electrodes 45, and a contact part 46 in the outer peripheral region 65. The first outer peripheral electrode 43, the connection electrode 44, and the plurality of second outer peripheral electrodes 45 are covered with the insulating layer 17.

The first outer peripheral electrode 43 is a buried electrode accommodated in a trench (not shown) formed in the outer peripheral region 65. The first outer peripheral electrode 43 is covered with the finger electrode part 522 of the second conductive film 52. The first outer peripheral electrode 43 may be made of the same material as the gate electrode 13.

The connection electrode 44 is a buried electrode accommodated in a trench (not shown) formed in the outer peripheral region 65. The connection electrode 44 may be made of the same material as the gate electrode 13. The connection electrode 44 electrically connects the gate electrode 13 and the first outer peripheral electrode 43. The connection electrode 44 is arranged to straddle between the element region 64 and the outer peripheral region 65. In other words, the connection electrode 44 crosses a boundary between the element region 64 and the outer peripheral region 65.

The second outer peripheral electrode 45 is a buried electrode accommodated in a trench (not shown) formed in the outer peripheral region 65. The second outer peripheral electrode 45 is arranged outside the first outer peripheral electrode 43. The second outer peripheral electrode 45 is formed in an annular shape surrounding an aggregate of transistor cells 14 formed in the element region 64. A plurality of second outer peripheral electrodes 45 (for example, ten or more second outer peripheral electrodes 45) may be formed. Some of the plurality of second outer peripheral electrodes 45 may be covered with the finger electrode part 522 of the second conductive film 52, and the rest may be formed outside the finger electrode part 522. The second outer peripheral electrode 45 is electrically isolated from the gate electrode 13 and the first outer peripheral electrode 43 and, in this embodiment, is an electrically floating electrode. The second outer peripheral electrode 45 may be made of the same material as the gate electrode 13.

The contact part 46 is connected to a third outer peripheral electrode 41 via a contact hole (not shown) formed in the insulating layer 17. The contact part 46 may contain W (tungsten). The finger electrode part 522 of the second conductive film 52 is electrically connected to the gate electrode 13 via the contact part 46, the first outer peripheral electrode 43, and the connection electrode 44. The finger electrode part 522 and the pad electrode part 521 are electrically connected to each other, so that the second conductive film 52 is electrically connected to the element part 20 via a path PP that is electrically separated from the first conductive film 51 (the first pad 7).

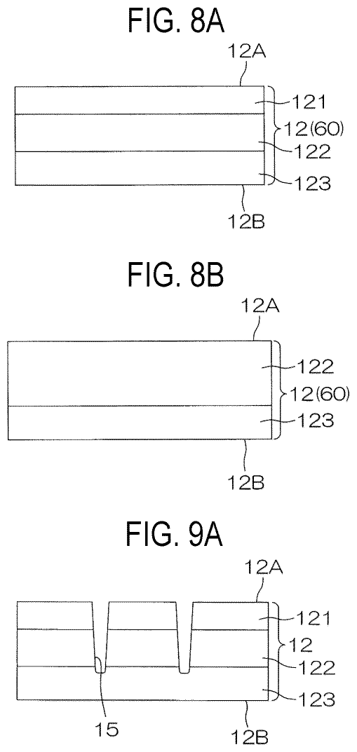

FIGS. 8A to 17A and 9B to 17B are views showing parts of a manufacturing process of the semiconductor element 3 in order of process. FIGS. 8A to 17A are longitudinal cross-sectional views of portions corresponding to FIG. 3. FIGS. 8B to 17B are longitudinal cross-sectional views of portions corresponding to FIG. 5. Note that in FIGS. 8A to 17A and 8B to 17B, among the reference numerals shown in FIGS. 3 and 5, only the reference numerals necessary for explaining the manufacturing process of the semiconductor element 3 are shown, and other reference numerals are omitted.

As shown in FIGS. 8A and 8B, in manufacturing the semiconductor device 1, first, a semiconductor wafer (not shown) is prepared. Next, a p-type epitaxial layer 60 is formed on the semiconductor wafer. A first main surface of the epitaxial layer and a second main surface on the opposite side of the first main surface may correspond to the first main surface 12A and the second main surface 12B, respectively. Next, p-type impurities and n-type impurities are selectively implanted into the surface layer portion of the first main surface 12A of the epitaxial layer 60 to form a p-type first impurity region 121 and an n-type second impurity region 122. Further, a p-type third impurity region 123 is formed in the remaining region of the epitaxial layer 60. As a result, a semiconductor chip 12 including the epitaxial layer 60 is formed.

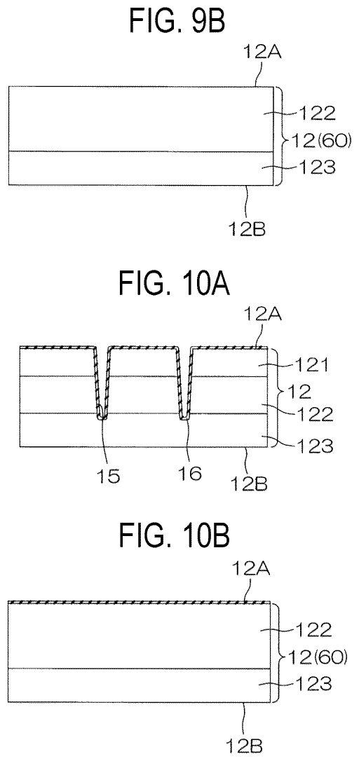

Next, as shown in FIGS. 9A and 9B, a gate trench 15 is formed. For example, a photoresist (not shown) is formed on the first main surface 12A of the semiconductor chip 12, and the gate trench 15 is selectively formed by etching through the photoresist.

Next, as shown in FIGS. 10A and 10B, the first main surface 12A of the semiconductor chip 12 and the inner surface of the gate trench 15 are oxidized by heat treatment such as a thermal oxidation method. As a result, a gate insulating film 16 is formed on the first main surface 12A and the inner surface of the gate trench 15.

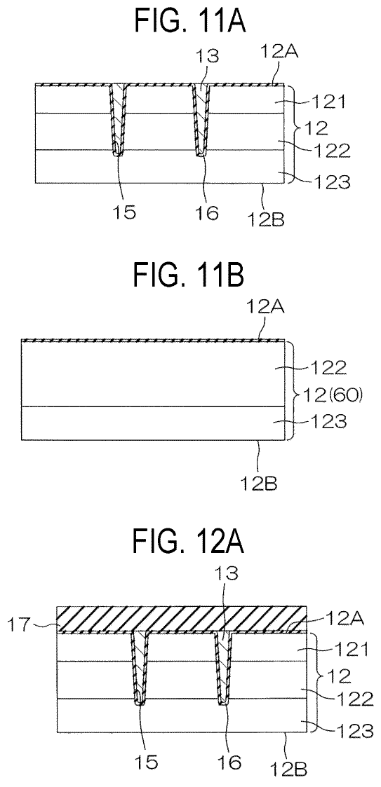

Next, as shown in FIGS. 11A and 11B, a gate electrode 13 is formed. A polysilicon film is formed on the gate insulating film 16 by, for example, a CVD method. Thereafter, unnecessary portions of the polysilicon film are removed by etching or the like, thereby forming the gate electrode 13. Further, by etching or the like, the gate insulating film 16 is removed from the first main surface 12A in a region shown in FIG. 11B while leaving the gate insulating film 16 in a region shown in FIG. 11A.

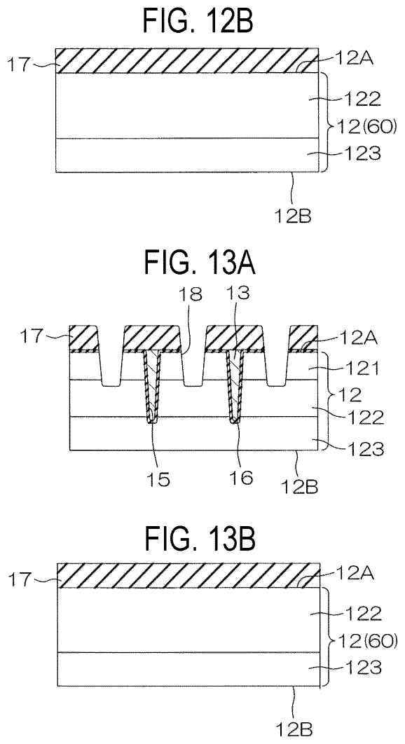

Next, as shown in FIGS. 12A and 12B, an insulating layer 17 is formed on the first main surface 12A by, for example, a CVD method. In a region shown in FIG. 12A, the insulating layer 17 is formed to cover the gate insulating film 16 and the gate electrode 13. On the other hand, in a region shown in FIG. 12B, the insulating layer 17 is formed to cover the gate insulating film 16 and the gate electrode 13.

Next, as shown in FIGS. 13A and 13B, a source trench 18 is formed by partially etching the insulating layer 17, the gate insulating film 16, the first impurity region 121, and the second impurity region 122.

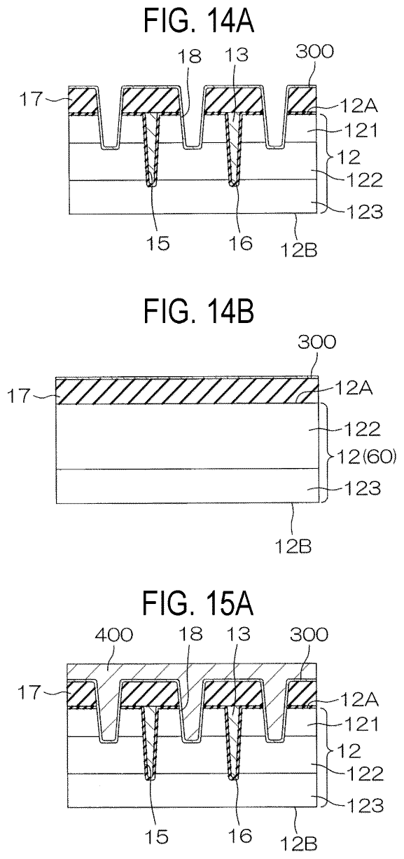

Next, as shown in FIGS. 14A and 14B, a barrier material film 300 is formed. For example, the barrier material film 300 is formed by depositing an electrode material using a sputtering method or the like. The barrier material film 300 includes, for example, a material containing Ti. The barrier material film 300 may include a stacked structure of Ti film and TiN film by first forming a Ti film by sputtering and then forming a TiN film on the Ti film by sputtering. The barrier material film 300 is continuously formed between and in contact with the inner surface of the source trench 18 and the upper surface of the insulating layer 17.

Next, as shown in FIGS. 15A and 15B, a deposited film 400 made of a conductive material is formed on the barrier material film 300 using, for example, a CVD method. The deposited film 400 fills the inside of the source trench 18. Thereafter, a resist mask 401 having a predetermined pattern is formed on the deposited film 400 in a region shown in FIG. 15B. In the region shown in FIG. 15B, the resist mask 401 includes a plurality of openings 402 that selectively expose a region where a deposit 92 is to be formed, and covers other regions.

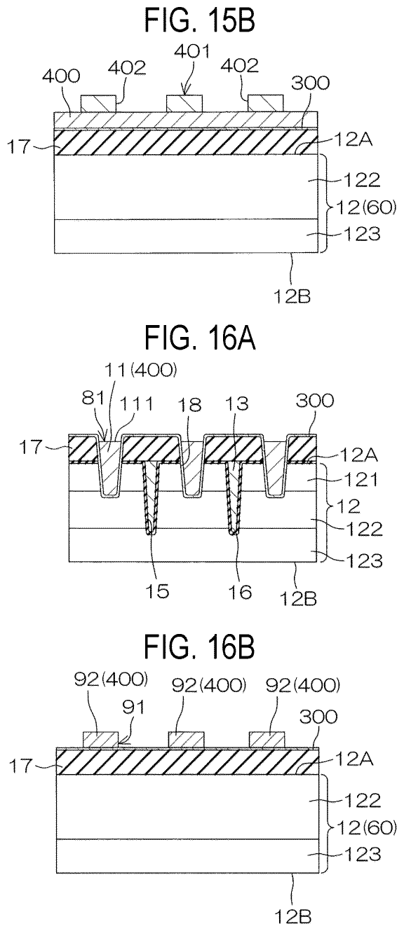

Next, as shown in FIGS. 16A and 16B, the deposited film 400 is removed from above the insulating layer 17 by etchback. In a region shown in FIG. 16A, a portion of the deposited film 400 remaining in the source trench 18 is formed as a contact plug 11. A first uneven structure 81 is formed by the upper surface 111 of the contact plug 11. The contact plug 11 includes a material containing, for example, W.

Further, in a region shown in FIG. 16B, a portion of the deposited film 400 is formed as a plurality of deposits 92 on the insulating layer 17. A second uneven structure 91 is formed by the plurality of deposits 92. The deposits 92 include a material containing, for example, W.

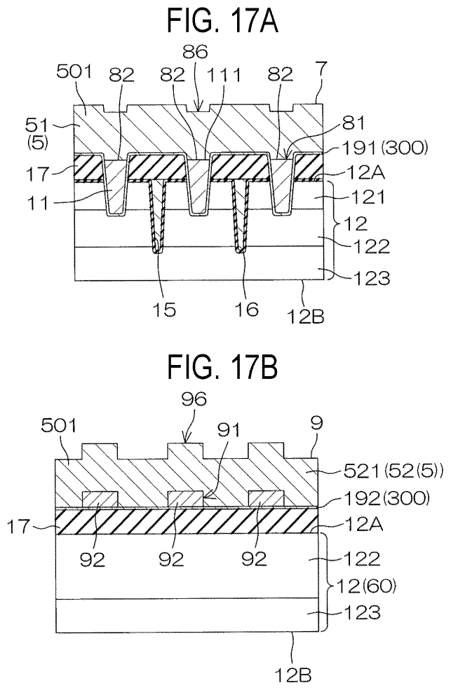

Next, as shown in FIGS. 17A and 17B, a conductive material film 501 is formed. For example, the conductive material film 501 is formed by depositing an electrode material on the barrier material film 300 using a sputtering method or the like. The conductive material film 501 may contain, for example, AlCu. Next, the conductive material film 501 and the barrier material film 300 are selectively etched to separate these films 300 and 501 into a plurality of regions. As a result, a first conductive film 51 and a second conductive film 52 of the conductive film 5 are formed. Additionally, a first barrier film 191 and a second barrier film 192 are formed. A surface uneven structure 86 is formed on the surface 51a of the first conductive film 51, and a surface uneven structure 96 is formed on the surface 52a of the second conductive film 52. Thereafter, an insulating material is deposited to cover the conductive film 5, and the insulating material is selectively etched to form a protective film 6 (not shown), thereby forming a first pad 7 and a second pad 9.

Next, after a drain electrode layer (not shown) is formed on a back surface of the semiconductor wafer by a vapor deposition method, a sputtering method, a plating method, or the like, a plurality of semiconductor elements 3 are cut out from the semiconductor wafer. The semiconductor element 3 is manufactured through the steps including the above.

From the above, according to this embodiment, as shown in FIG. 5, in the insulating layer 17 below the second pad 9, that is, in the non-element region 66, the second uneven structure 91 is formed by the deposits 92 deposited on the insulating layer 17. The second pad 9 includes the surface uneven structure 96 that takes after the shape of the second uneven structure 91. This increases the contact area between the second wire 10 (see FIG. 1) and the second pad 9. Therefore, the adhesion between the tip 10a of the second wire 10 and the second pad 9 can be enhanced. Therefore, the wire bonding strength can be improved in the second pad 9 formed above the non-element region 66.

Further, as shown in FIG. 3, in the insulating layer 17 below the first pad 7, that is, in the element region 64, the first uneven structure 81 is formed by the upper surface of the insulating layer 17 and the upper surface 111 of the conductive contact plug 11 buried in the insulating layer 17. The first pad 7 includes the surface uneven structure 86 that takes after the shape of the first uneven structure 81. This increases the contact area between the first wire (see FIG. 1) and the first pad 7. Therefore, the adhesion between the tip 8a of the first wire 8 and the first pad 7 can be enhanced. Therefore, the wire bonding strength at the first pad 7 can be improved.

From the above, the wire bonding strength can be improved in both the first pad 7 and the second pad 9 which are electrically isolated from each other.

Further, since the deposits 92 of the second uneven structure 91 are made of the same material as the contact plug 11, the deposits 92 of the second uneven structure 91 can be formed at the same time as the contact plug 11. In this case, as compared to a case where the deposits 92 of the second uneven structure 91 are formed separately from the contact plug 11, the number of steps in the manufacturing process of the semiconductor device 1 can be reduced.

Further, the second uneven structure 91 is formed not only below the wire connection region 93 but also below the test region 94. Therefore, even if part or all of the tip 10a of the second wire 10 is connected to the test region 94 due to positional deviation during patterning or wire bonding, the bonding strength of the second wire 10 can be maintained high.

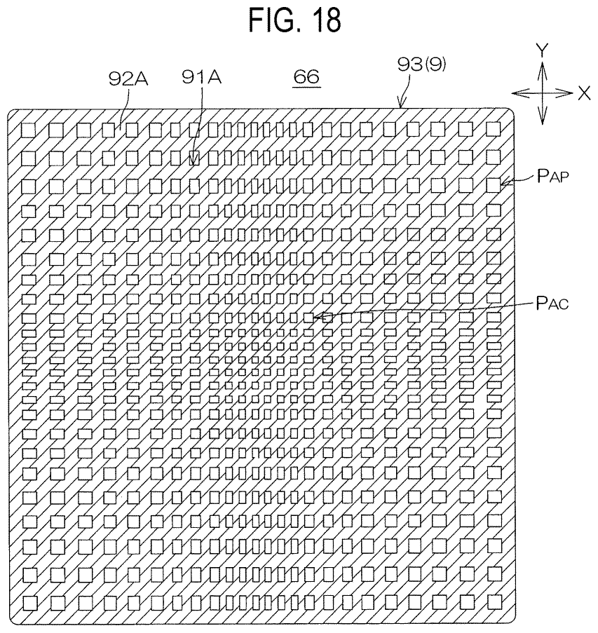

FIGS. 18 to 24 are views showing layouts of second uneven structures 91A to 91G according to first to seventh modifications of the present disclosure. FIGS. 18 to 24 are views of portions corresponding to FIG. 6. In FIGS. 18 to 24, deposits 92A to 92G are shown by hatched regions, as in the case of FIG. 6.

Like the second uneven structure 91 shown in FIG. 6, the second uneven structure 91A shown in FIG. 18 includes the deposits 92A (the unevenness) arranged in a lattice shape, in a plan view. In the second uneven structure 91A, patterns P_{AP} formed on the peripheral edge portion of the second pad 9 (the wire connection region 93) are formed sparser than patterns P_{AC} formed on the central portion of the second pad 9 (the wire connection region 93).

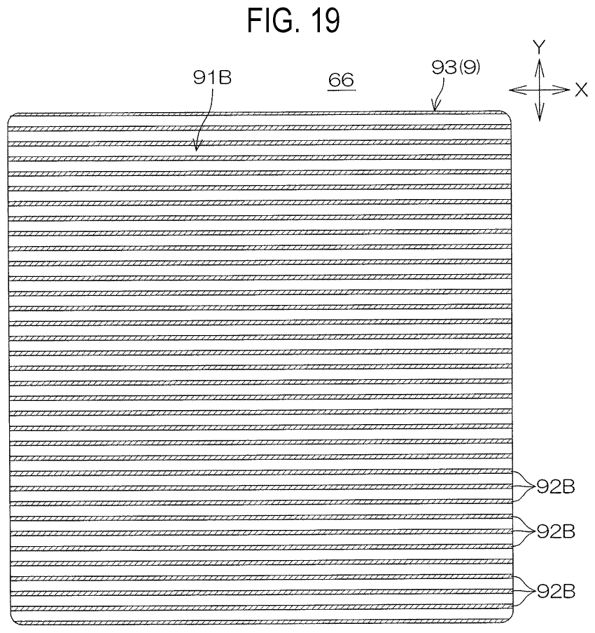

The second uneven structure 91B shown in FIG. 19 includes a plurality of deposits (the unevenness) 92B extending along the first direction X and having a stripe shape in a plan view. The plurality of deposits 92B are arranged at equal intervals in the second direction Y. The plurality of deposits 92B may have a stripe shape extending along the second direction Y.

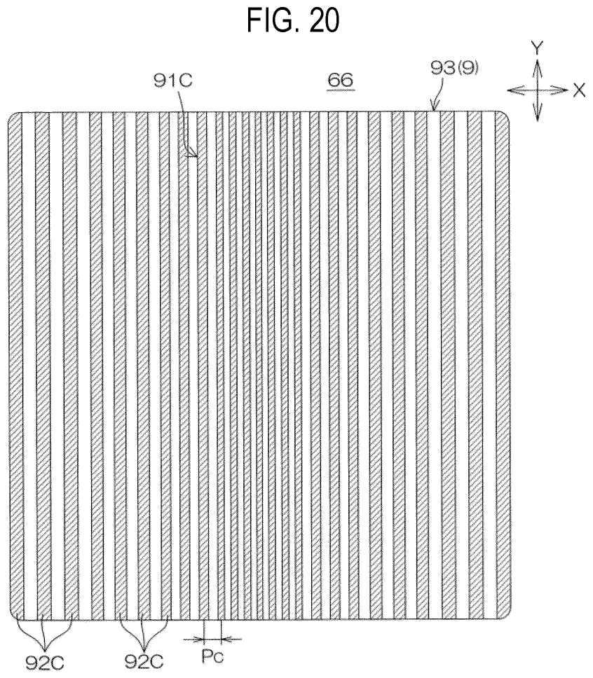

The second uneven structure 91C shown in FIG. 20 includes a plurality of deposits (the unevenness) 92C extending along the second direction Y and having a stripe shape in a plan view. The pitch P_{C} of the plurality of deposits 92C included in the second uneven structure 91C becomes narrower toward both ends in the first direction X. The plurality of deposits 92C may have a stripe shape extending along the first direction X.

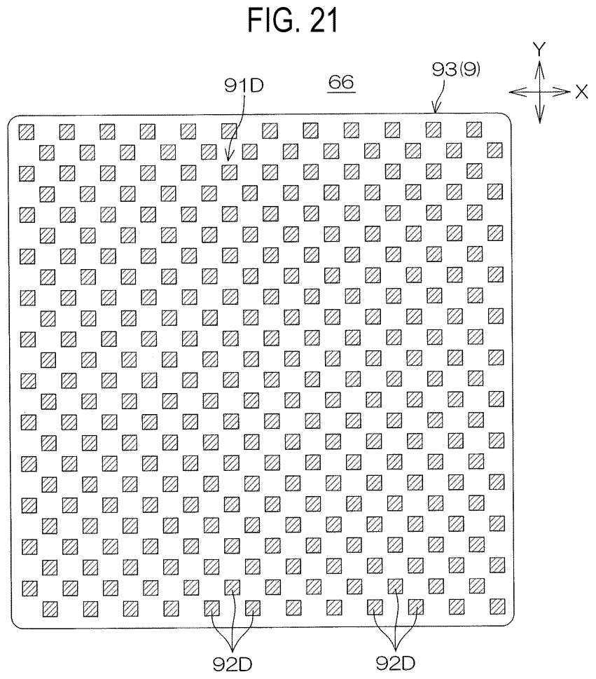

The second uneven structure 91D shown in FIG. 21 includes a plurality of deposits 92D arranged in a dot shape, in a plan view. A large number of deposits 92D are arranged at a uniform density over the entire region of the second pad 9 (the wire connection region 93).

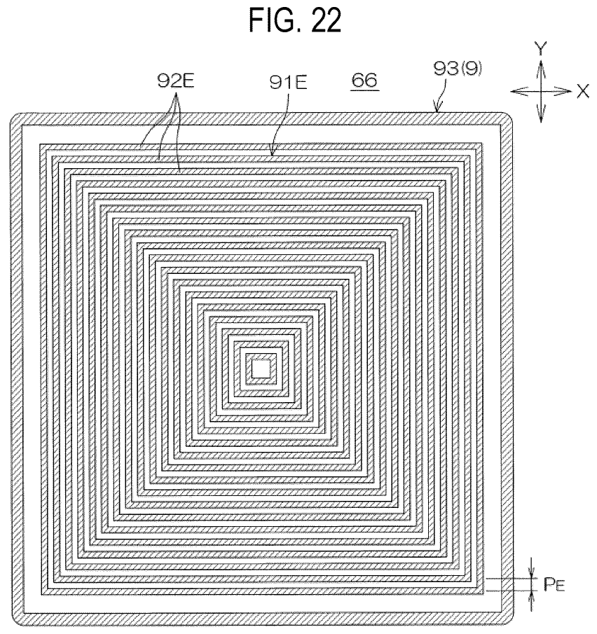

The second uneven structure 91E shown in FIG. 22 includes the deposits 92E arranged in multiple square annular shapes, in a plan view. The square annular deposits 92E are adjacent to each other inside and outside at a constant pitch P_{E}.

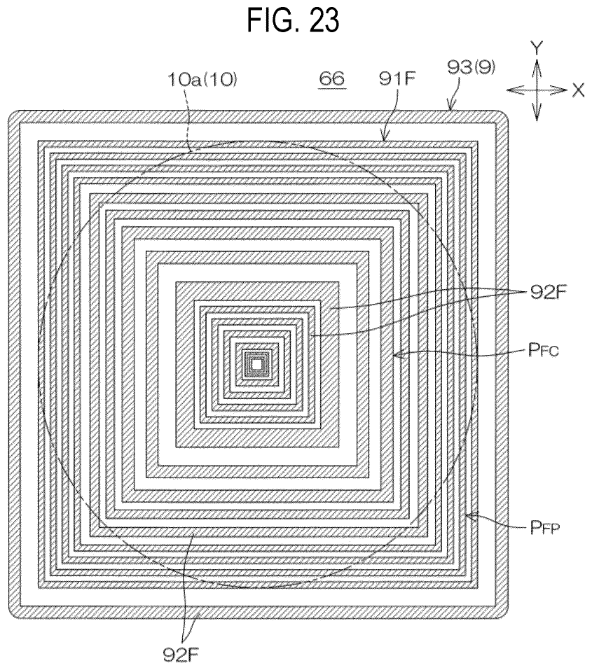

The second uneven structure 91F shown in FIG. 23 includes the deposits 92F arranged in multiple square annular shapes, in a plan view. The second uneven structure 91F includes first patterns P_{FC} formed on the central portion of the second pad 9 and second patterns P_{FP} formed on the peripheral edge portion of the second pad 9 in a plan view. The second patterns P_{FP} are formed denser than the first patterns P_{FC}. In this case, with the tip 10a of the second wire 10 connected, the peripheral edge portion of the tip 10a is bonded to the denser second patterns P_{FP}. As a result, the adhesion of the tip 10a of the second wire 10 can be further improved.

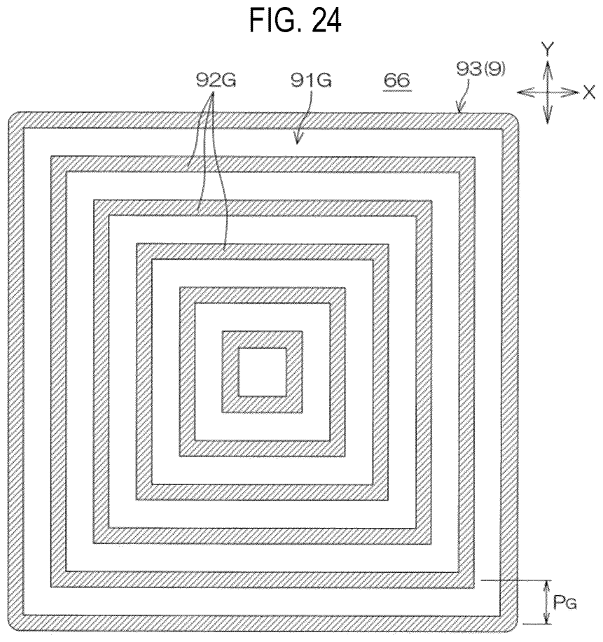

The second uneven structure 91G shown in FIG. 24 includes multiple (for example, 6-fold) square annular deposits 92G. The deposits 92G are adjacent to each other inside and outside at a constant pitch P_{G}. The pitch P_{G}is larger than the pitch P_{E}.

Further, the second uneven structure 91 and the second uneven structures 91A to 91G may not be formed below the test region 94, but may be formed only below the wire connection region 93.

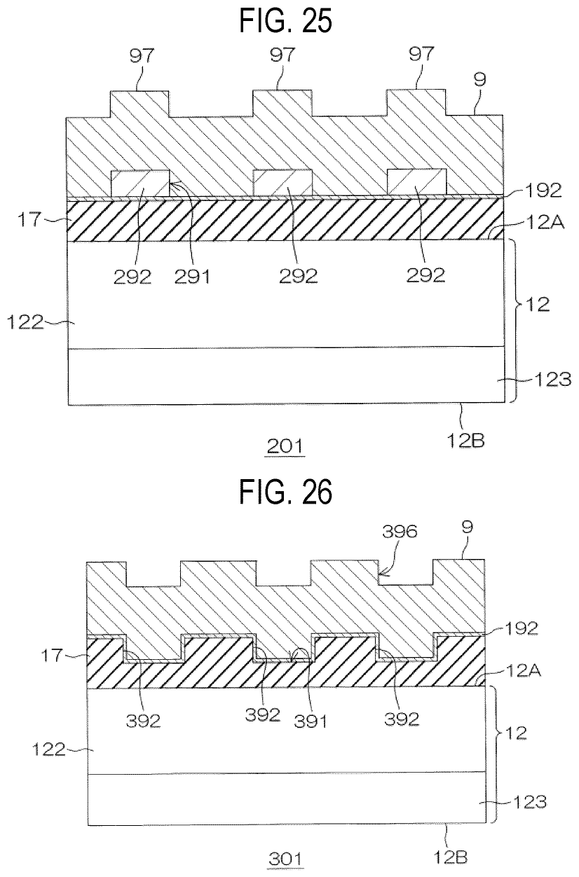

FIG. 25 is a view showing a cross-section of a semiconductor device 201 according to a second embodiment of the present disclosure. The semiconductor device 201 according to the second embodiment is different from the semiconductor device 1 in that a second uneven structure 291 is provided instead of the second uneven structure 91. A plurality of deposits 292 forming the second uneven structure 291 are made of a material different from that of a contact plug 11. The deposits 292 are made of, for example, polysilicon. In this case, the plurality of deposits s 292 and the contact plug 11 are formed in different steps.

FIG. 26 is a view showing a cross-section of a semiconductor device 301 according to a third embodiment of the present disclosure. The semiconductor device 301 according to the third embodiment is different from the semiconductor device 1 in that a second uneven structure 391 is provided instead of the second uneven structure 91. The second uneven structure 391 is formed by a plurality of grooves 392. The plurality of grooves 392 are formed on an upper surface of an insulating layer 17. The plurality of grooves 392 do not penetrate the insulating layer 17 in a thickness direction of the insulating layer 17. A surface uneven structure 396 that takes after a shape of the second uneven structure 391 is formed on a second pad 9.

Although the plurality of embodiments of the present disclosure have been described above, the present disclosure can also be implemented in other forms.

Further, for example, a configuration may be adopted in which the conductivity types of semiconductor portions of the semiconductor devices 1, 201, and 301 are reversed. For example, in the semiconductor devices 1, 201, and 301, the p-type portion may be n-type, and the n-type portion may be p-type.

Further, in each of the above-described embodiments, MISFET is adopted as an example of the element structure of the semiconductor devices 1, 201, and 301, but the element structure of the semiconductor devices 1, 201, and 301 may be, for example, an IGBT (Insulated Gate Bipolar Transistor) or the like.

Others, various design changes can be made within the scope of matters described in the claims.

The features described below can be extracted from the description of the present disclosure and drawings.

### Supplementary Note 1-1

A semiconductor device (1, 201) including: a semiconductor chip (12) including a first main surface (12A) and a second main surface (12B) opposite to the first main surface (12A);
an element region (64) formed on the first main surface (12A) and including an element part (20), and a non-element region (66) outside the element region (64);
an insulating layer (17) covering the element region (64) and the non-element region (66);
a first pad (7) formed on the insulating layer (17) and electrically connected to the element part (20);
a second pad (9) formed on the insulating layer (17) and electrically connected to the element part (20) via a path (PP) electrically separated from the first pad (7);
a first uneven structure (81) formed by a buried body (11), which has conductivity and is buried in the insulating layer (17), below the first pad (7) of the insulating layer (17); and
a second uneven structure (91, 91A to 91G, 291) formed by deposits (92, 92A to 92G, 292) deposited on a surface of the insulating layer (17), below the second pad (9) of the insulating layer (17).

With the semiconductor device (1) according to an embodiment of the present disclosure, below the first pad (7), the first uneven structure (81) is formed by the buried body (11), which has conductivity and is buried in the insulating layer (17). The first pad (7) includes an uneven structure (86) that takes after a shape of the first uneven structure (81). This increases a contact area between the first pad (7) and a wiring member (8) bonded to the first pad (7). Therefore, in a state where the wiring member (8) is connected, an adhesion between the wiring member (8) and the first pad (7) can be enhanced, and a bonding strength of the wiring member (8) at the first pad (7) can be improved.

Further, below the second pad (9), the second uneven structure (91, 91A to 91G, 291) is formed by the deposits (92, 92A to 92G, 292) deposited on the surface of the insulating layer (17). The second pad (9) includes an uneven structure (96) that takes after a shape of the second uneven structure (91, 91A to 91G, 291). This increases a contact area between the second pad (9) and a wiring member (10) bonded to the second pad (9). Therefore, in a state where the wiring member (10) is connected, an adhesion between the wiring member (10) and the second pad (9) can be enhanced, and a bonding strength of the wiring member (10) at the second pad (9) can be improved.

From the above, the wire bonding strength can be improved in both the first pad (7) and the second pad (9).

### Supplementary Note 1-2

The semiconductor device (1, 201) of Supplementary Note 1-1, wherein the first uneven structure (81) is formed in the element region (64), and
wherein the second uneven structure (91, 91A to 91G, 291) is formed in the non-element region (66).

### Supplementary Note 1-3

The semiconductor device (1) of Supplementary Note 1-1 or 1-2, wherein the buried body (11) of the first uneven structure (81) and the deposits (92, 92A to 92G) of the second uneven structure (91, 91A to 91G) are made of a same material.

### Supplementary Note 1-4

The semiconductor device (201) of any one of Supplementary Notes 1-1 to 1-3, wherein the buried body (11) of the first uneven structure (81) and the deposits (292) of the second uneven structure (291) are made of different materials.

### Supplementary Note 1-5

The semiconductor device (1) of any one of Supplementary Notes 1-1 to 1-3, wherein the buried body (11) of the first uneven structure (81) includes a contact plug (11) buried in the insulating layer (17) and connected to the element part (20).

### Supplementary Note 1-6

The semiconductor device (1, 201) of any one of Supplementary Notes 1-1 to 1-5, wherein an unevenness (92, 92A to 92G, 292) of the second uneven structure (91, 91A to 91G, 291) is larger than an unevenness (82) of the first uneven structure (81).

### Supplementary Note 1-7

The semiconductor device (1, 201) of any one of Supplementary Notes 1-1 to 1-6, wherein the second pad (9) includes a wire connection region (93) for connecting a bonding wire (10) and a test region (94) for contacting a test member for testing, and wherein the second uneven structure (91, 91A to 91G, 291) is formed both below the wire connection region (93) and below the test region (94).

### Supplementary Note 1-8

The semiconductor device (1, 201) of any one of Supplementary Notes 1-1 to 1-7, wherein the first pad (7) is an output pad of the element part (20).

### Supplementary Note 1-9

The semiconductor device (1, 201) of any one of Supplementary Notes 1-1 to 1-8, wherein the second pad (9) is a control pad which controls a current of the element part (20).

### Supplementary Note 1-10

The semiconductor device (1, 201) of any one of Supplementary Notes 1-1 to 1-9, wherein the deposits (92E to 92G) of the second uneven structure (91E to 91G) are arranged in multiple annular shapes in a plan view.

### Supplementary Note 1-11

The semiconductor device (1, 201) of any one of Supplementary Notes 1-1 to 1-9,wherein the deposits (92, 92A) of the second uneven structure (91, 91A) are arranged in a lattice shape in a plan view.

### Supplementary Note 1-12

The semiconductor device (1, 201) of any one of Supplementary Notes 1-1 to 1-11, wherein the second uneven structure (91F) includes a first pattern (P_{FC}) formed on a central portion of the second pad (9), and a second pattern (P_{FP}), which is formed on a peripheral edge portion of the second pad (9) and is formed to be denser than the first pattern (P_{FC}), in a plan view.

### Supplementary Note 1-13

The semiconductor device (1, 201) of any one of Supplementary Notes 1-1 to 1-12, wherein a thickness (T₂) of the deposits (92, 92A to 92G, 292) of the second uneven structure (91, 91A to 91G, 291) is 250 nm or more and 350 nm or less.

### Supplementary Note 1-14

The semiconductor device (1, 201) of any one of Supplementary Notes 1-1 to 1-13, further including: a bonding wire (10) which includes an Au wire or a Cu wire and is connected to the second pad (9).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip including a first main surface and a second main surface opposite to the first main surface;
an element region formed on the first main surface and including an element part, and a non-element region outside the element region;
an insulating layer covering the element region and the non-element region;
a first pad formed on the insulating layer and electrically connected to the element part;
a second pad formed on the insulating layer and electrically connected to the element part via a path electrically separated from the first pad;
a first uneven structure formed by a buried body, which has conductivity and is buried in the insulating layer, below the first pad of the insulating layer; and
a second uneven structure formed by deposits deposited on a surface of the insulating layer, below the second pad of the insulating layer.

2. The semiconductor device of claim 1, wherein the first uneven structure is formed in the element region, and
wherein the second uneven structure is formed in the non-element region.

3. The semiconductor device of claim 1, wherein the buried body of the first uneven structure and the deposits of the second uneven structure are made of a same material.

4. The semiconductor device of claim 1, wherein the buried body of the first uneven structure and the deposits of the second uneven structure are made of different materials.

5. The semiconductor device of claim 1, wherein the buried body of the first uneven structure includes a contact plug buried in the insulating layer and connected to the element part.

6. The semiconductor device of claim 1, wherein an unevenness of the second uneven structure is larger than an unevenness of the first uneven structure.

7. The semiconductor device of claim 1, wherein the second pad includes a wire connection region for connecting a bonding wire and a test region for contacting a test member for testing, and
wherein the second uneven structure is formed both below the wire connection region and below the test region.

8. The semiconductor device of claim 1, wherein the first pad is an output pad of the element part.

9. The semiconductor device of claim 1, wherein the second pad is a control pad which controls a current of the element part.

10. The semiconductor device of claim 1, wherein the deposits of the second uneven structure are arranged in multiple annular shapes in a plan view.

11. The semiconductor device of claim 1, wherein the deposits of the second uneven structure are arranged in a lattice shape in a plan view.

12. The semiconductor device of claim 1, wherein the second uneven structure includes a first pattern formed on a central portion of the second pad, and a second pattern, which is formed on a peripheral edge portion of the second pad and is formed to be denser than the first pattern, in a plan view.

13. The semiconductor device of claim 1, wherein a thickness of the deposits of the second uneven structure is 250 nm or more and 350 nm or less.

14. The semiconductor device of claim 1, further comprising:
a bonding wire which includes an Au wire or a Cu wire and is connected to the second pad.
